(19) United States
(12) Patent Application Publication
(10) Pub. No.: US 2008/0178806 A1
(43) Pub. Date: Jul. 31, 2008

(54) Plasma Source For Uniform Plasma Distribution in Plasma Chamber

(75) Inventor: Nam Hun Kim, Gyeonggi-do (KR)

Correspondence Address: MORGAN & FINNEGAN, L.L.P., 3 WORLD FINANCIAL CENTER, NEW YORK, NY, 10281-2101, US

(73) Assignee: ADAPTIVE PLASMA TECHNOLOGY CORP., Gyeonggi-so (KR)

(21) Appl. No.: 11/665,211

(22) PCT Filed: May 27, 2005
(86) PCT No.: PCT/KR05/01584

§ 371 Date: Apr. 11, 2007

(30) Foreign Application Priority Data
Oct. 13, 2004 (KR) 10-2004-0081765

(51) Int. Cl. C23C 16/44

(52) U.S. Cl. 118/723 R

(57) ABSTRACT

Disclosed herein is a plasma source which can create plasma within a reaction chamber to process a semiconductor wafer. The plasma source comprises a bushing equipped at an upper center of the reaction chamber, and a plurality of source coils linearly extending from the bushing to a periphery of the reaction chamber. With the linear source coils, it is possible to prevent deviation in magnetic field from the center to the periphery of the plasma source in the radial direction, resulting in easy control of critical dimensions and uniform etching rate both at the center and periphery of the reaction chamber.

### BACKGROUND OF THE INVENTION

1. Field of the Invention

The present invention relates to a plasma chamber, and, more particularly, to a plasma source for uniform distribution of plasma in a plasma chamber.

2. Description of the Related Art

Technology of manufacturing ultra-large scale integrated circuit devices has developed remarkably over the past twenty years. Such development could be accomplished by virtue of semiconductor manufacturing apparatuses which can support processes requiring advanced techniques. A plasma chamber, one of such semiconductor manufacturing apparatuses, has been widened in its applications, and, for example, is now used for a deposition process as well as an etching process.

The plasma chamber is a semiconductor manufacturing apparatus to create plasma therein, and performs a process such as an etching process or a deposition process using the plasma. The plasma chamber can be classified into an electron-cyclotron resonance plasma (ECRP) source chamber, a helicon-wave excited plasma (HWEP) source chamber, an inductively coupled plasma (ICP) source chamber, a capacitively coupled plasma (CCP) course chamber, and the like, according to a plasma source. Recently, there has been suggested an adaptive plasma source chamber, which can provide both advantages of the CCP source and the ICP source.

FIG. 1 is a schematic cross-sectional view illustrating a plasma chamber comprising a conventional plasma source. FIG. 2 is a plan view illustrating the plasma source of FIG. 1.

In FIGS. 1 and 2, the plasma chamber 100 comprises a reaction space 104 defined to predetermined dimensions by a chamber outer wall 102 and a dome 112. Plasma 120 is produced in a predetermined region of the reaction space 104 under a predetermined condition. Although the reaction space 104 is shown as being opened at a lower portion of the plasma chamber 100 in the drawing, this structure is simplified for description, and in practice, the lower portion of the plasma chamber 100 is also shielded from the outside, so that the plasma chamber 100 is under vacuum. A wafer supporting station 106 is provided to the lower portion of the plasma chamber 100 to mount a semiconductor wafer 108 to be processed thereon. The wafer supporting station 106 is connected to an external RF power source 116. Although not shown in the drawings, the wafer supporting plate 106 may have a heater disposed therein.

A plasma source 200 is provided on an outer surface of the dome 112 to produce plasma. As shown in FIG. 2, the plasma source 200 comprises a plurality of unit coils, for example, first, second, third, and fourth unit coils 131, 132, 133 and 134, and a bushing 120. More specifically, the bushing 120 is located at the center of the plasma source 200, and the first, second, third, and fourth unit coils 131, 132, 133 and 134 spirally extend from the bushing 120 to surround the bushing 120. Although four unit coils are illustrated in the example, the number of unit coils is not limited to four unit coils, as a matter of course. The bushing 120 has a supporting rod 140 disposed at the center of the busing 120 and perpendicularly protruding from an upper surface of the bushing 120. The supporting rod 140 is connected to one terminal of the RF power source 114. Another terminal of the RF power source is grounded. Power is supplied from the RF power source 114 to the first, second, third, and fourth unit coils 131, 132, 133 and 134 via the supporting rod 140 and the bushing 120.

The conventional plasma source 200 has a circular shape extending from the bushing 120 and surrounding the bushing 120. With this structure, the plasma source 200 has a magnetic field intensity given by the following equation:

∂B/∂t=−∇×E (1)

where B denotes magnetic flux density, ∇ denotes a delta operator, and E denotes electric field intensity.

Generation of the magnetic field according to the Maxwell equation as mentioned above is applied to most plasma sources having the circular shape. However, the conventional plasma source has problems in that it suffers deviation in magnetic field from the center of the plasma source to an outer periphery thereof, resulting in difficulty to control critical dimensions and uniform etching rate, in particular, at the center and the outer periphery of the plasma source.

### SUMMARY OF THE INVENTION

Therefore, the present invention has been made in view of the above problems, and it is an object of the present invention to provide a plasma source, which produces a uniform distribution of magnetic field in both an azimuth angle and a radial direction to create uniform distribution of plasma within a plasma chamber.

In accordance with an aspect of the present invention, the above and other objects can be accomplished by the provision of a plasma source for producing plasma within a reaction chamber for processing a semiconductor wafer, comprising: an electrically conductive bushing equipped at an upper center of the reaction chamber; and a plurality of source coils linearly extending from the bushing to a periphery of the reaction chamber.

The plurality of source coils may be disposed in a symmetrical arrangement.

Each of the source coils may have a non-constant thickness from a portion connected to the bushing to the periphery of the reaction chamber.

The plasma source may further comprise a peripheral source coil separated from the bushing by a predetermined distance while surrounding the bushing around an upper periphery of the reaction chamber, and having a circular shape to connect all the plurality of source coils to each other.

In this case, the plasma source may further comprise at least one middle source coil separated from the bushing by a predetermined distance while surrounding the bushing between the bushing and the peripheral source coil, and having a circular shape to connect all the plurality of source coils to each other.

In accordance with another aspect, a plasma source for producing plasma within a reaction chamber for processing a semiconductor wafer is provided, comprising: an electrically conductive bushing equipped at an upper center of the reaction chamber; a plurality of first source coils radially extending from the bushing in a first region surrounding the bushing to a periphery of the first region, each first source coil having a shape curved towards an upper portion of the reaction chamber; and a plurality of second source coils spirally extending from the first source coils in a second region surrounding the first region to a periphery of the second region.

In accordance with yet another aspect, a plasma source for producing plasma within a reaction chamber for processing a semiconductor wafer is provided, comprising: an electrically conductive bushing equipped at an upper center of the reaction chamber; and a plurality of source coils extending in a wave shape from the bushing to a periphery of the reaction chamber.

In accordance with yet another aspect, a plasma source for producing plasma within a reaction chamber for processing a semiconductor wafer is provided, comprising: a plurality of source coils linearly extending from an upper center of the reaction chamber to a periphery of the reaction chamber; and a circular peripheral source coil connecting all distal ends of the plurality of source coils around an upper periphery of the reaction chamber.

In this case, the plasma source may further comprise at least one middle source coil circularly disposed within the peripheral source coil while being separated a predetermined distance from the peripheral source coil to connect all the source coils.

In accordance with yet another aspect, a plasma source for producing plasma within a reaction chamber for processing a semiconductor wafer is provided, comprising: an electrically conductive bushing equipped at an upper center of the reaction chamber, the bushing comprising a first section having a greater area and being located at a lower portion of the reaction chamber, and a second section having a smaller area and being located on an upper surface of the first section; a plurality of source coils extending in a wave shape from the first section of the bushing to a periphery of the reaction chamber; and a circular peripheral source coil connecting all distal ends of the source coils at an upper periphery of the reaction chamber.

The first section may be gradually decreased from a bottom surface to a portion contacting the second section.

In accordance with yet another aspect, a plasma source for producing plasma within a reaction chamber for processing a semiconductor wafer is provided, comprising: an electrically conductive bushing equipped at an upper center of the reaction chamber; at least one middle source coil surrounding the bushing; a plurality of first linear source coils linearly extending from the bushing to the middle source coil; a peripheral source coil surrounding the middle source coil; and a plurality of second linear source coils linearly extending from the first linear source coils to the peripheral source coil, wherein the middle source coil and the first linear source coils are formed of a material different from that of the peripheral source coil and the second linear source coils.

In accordance with yet another aspect, a plasma source for producing plasma within a reaction chamber for processing a semiconductor wafer is provided, comprising: an electrically conductive bushing equipped at an upper center of the reaction chamber; a peripheral source coil surrounding the bushing; and a plurality of linear source coils linearly extending from the bushing to the peripheral source coil, wherein the bushing, the peripheral source coil, and the linear source coils are formed of different materials.

In accordance with yet another aspect, a plasma source for producing plasma within a reaction chamber for processing a semiconductor wafer is provided, comprising: an electrically conductive bushing equipped at an upper center of the reaction chamber; a plurality of first source coils extending in a wave shape from the bushing to a first region separated by a first distance from the bushing while surrounding the bushing; and a plurality of second source coils spirally extending from the first source coils to a second region separated by a second distance from the first region while surrounding the first region.

In accordance with yet another aspect, a plasma source for producing plasma within a reaction chamber for processing a semiconductor wafer is provided, comprising: an electrically conductive columnar-shaped bushing vertically located at an upper center of the reaction chamber, the bushing having an upper surface positioned a substantial distance from the reaction chamber and a lower surface adjacent the reaction chamber; a plurality of upper source coils extending in a wave shape from the bushing to a periphery of the reaction chamber, and coplanar with the upper surface of the bushing; and a plurality of lower source coils extending in a wave shape from the bushing to the periphery of the reaction chamber, and coplanar with the lower surface of the bushing.

The plasma source may further comprise an upper peripheral source coil coplanar with the upper surface of the bushing and connecting distal ends of the upper source coils; a lower peripheral source coil coplanar with the lower surface of the bushing and connecting distal ends of the lower source coils; and a vertical source coil vertically connecting the upper peripheral source coil and the lower peripheral source coil.

In accordance with yet another aspect, a plasma source for producing plasma within a reaction chamber for processing a semiconductor wafer is provided, comprising: an electrically conductive columnar-shaped bushing vertically located at an upper center of the reaction chamber, the bushing having an tipper surface positioned a substantial distance from the reaction chamber and a lower surface adjacent the reaction chamber; a plurality of upper source coils linearly extending from the bushing to a periphery of the reaction chamber, and coplanar with the upper surface of the bushing; and a plurality of lower source coils linearly extending from the bushing to the periphery of the reaction chamber, and coplanar with the lower surface of the bushing.

The plasma source may further comprise a peripheral upper source coil coplanar with the upper surface of the bushing and connecting all distal ends of the upper source coils; at least one middle upper source coil located coplanar with the upper surface of the bushing between the bushing and the peripheral upper source coil; a peripheral lower source coil circularly located coplanar with the lower surface of the bushing and connecting all distal ends of the lower source coils; at least one middle lower source coil located coplanar with the lower surface of the bushing between the bushing and the peripheral lower source coil; and a vertical source coil vertically connecting the peripheral upper source coil and the peripheral lower source coil.

In accordance with yet another aspect, a plasma source for producing plasma within a reaction chamber for processing a semiconductor wafer is provided, comprising: an electrically conductive upper bushing located on an upper plane positioned a substantial distance from the reaction chamber; a plurality of first upper source coils extending in a wave shape from the upper bushing to a first region separated by a first distance from the upper bushing; a plurality of second upper source coils spirally extending from the first upper source coils on the upper plane to a second region separated by a second distance from the first region while surrounding the first region; a peripheral upper source coil connecting distal ends of the second upper source coils on the upper plane; an electrically conductive lower bushing located on a lower plane adjacent the reaction chamber; a plurality of first lower source coils extending in a wave shape from the lower bushing to a third region separated by a third distance from the lower bushing; a plurality of second lower source coils spirally extending from the first lower source coils on the lower plane to a fourth region separated by a fourth distance from the third region while surrounding the third region; a peripheral lower source coil connecting distal ends of the second lower source coils on the lower plane; and a vertical source coil vertically connecting the peripheral upper source coil and the peripheral lower source coil.

In accordance with yet another aspect, a plasma source for producing plasma within a reaction chamber for processing a semiconductor wafer is provided, comprising: a bushing located at a center of the reaction chamber; and a plurality of conductors radially extending in a stripe shape from the bushing.

The conductors may be disposed symmetrically.

The bushing may comprise a conductive material.

Each of the conductors may have a thickness gradually increasing from the bushing to the edge of the reaction chamber.

Each of the conductors may have a thickness gradually decreasing from the bushing to edge of the reaction chamber.

In accordance with yet another aspect, a plasma source for producing plasma within a reaction chamber for processing a semiconductor wafer is provided, comprising: a bushing located at a center of the reaction chamber; and a plurality of conductors radially extending in a curved-stripe shape from the bushing.

The conductors may be disposed symmetrically.

The bushing may comprise a conductive material.

Each of the conductors may have an S-shape or W-shape.

Each of the conductors may have a thickness gradually increasing from the bushing to edge of the reaction chamber.

Each of the conductors may have a thickness gradually decreasing from the bushing to edge of the reaction chamber.

One of the advantages of the present invention is that, since the plasma source comprises non-circular, i.e. linear, source coils, it is possible to prevent deviation in magnetic field from the center to a periphery of the reaction chamber in the radial direction, resulting in easy control of critical dimensions and uniform etching rate both at the center and periphery of the plasma source. Another advantage of the present invention is that, since conductors radially extending from the bushing at the center of a reaction chamber are disposed in a stripe shape or curved-stripe shape, a magnetic field is circularly induced, so that a magnetic field is uniformly distributed in both an azimuth angle and a radial direction, resulting in enhanced selectivity and uniform CD distribution.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a schematic cross-sectional view illustrating a plasma chamber employing a conventional plasma source;

FIG. 2 is a plan view illustrating the conventional plasma source of FIG. 1;

FIG. 3 is a plan view illustrating a plasma source in accordance with one embodiment of the present invention;

FIG. 4 is a cross-sectional view illustrating the plasma source of FIG. 3;

FIG. 5 is a plan view illustrating a plasma source in accordance with another embodiment of the present invention;

FIG. 6 is a cross-sectional view illustrating tie plasma source of FIG. 5;

FIG. 7 is a plan view illustrating a plasma source in accordance with yet another embodiment of the present invention;

FIG. 8 is a plan view illustrating a plasma source in accordance with yet another embodiment of the present invention;

FIG. 9 is a graph depicting the/a relationship between coil thickness and distance from the center of the plasma source of FIG. 8;

FIG. 10 is a plan view illustrating a plasma source in accordance with yet another embodiment of the present invention;

FIG. 11 is a plan view illustrating a plasma source in accordance with yet another embodiment of the present invention;

FIG. 12 is a plan view illustrating a plasma source in accordance with yet another embodiment of the present invention;

FIG. 13 is a cross-sectional view illustrating the plasma source of FIG. 11;

FIG. 14 is a plan view illustrating a plasma source in accordance with yet another embodiment of the present invention;

FIG. 15 is a cross-sectional view illustrating the plasma source of FIG. 14;

FIG. 16 is a plan view illustrating a plasma source in accordance with yet another embodiment of the present invention;

FIG. 17 is a plan view illustrating a plasma source in accordance with yet another embodiment of the present invention;

FIG. 18 is a plan view illustrating a plasma source in accordance with yet another embodiment of the present invention;

FIG. 19 is a plan view illustrating a plasma source in accordance with yet another embodiment of the present invention;

FIG. 20 is a plan view illustrating a plasma source in accordance with yet another embodiment of the present invention;

FIG. 21 is a plan view illustrating a plasma source in accordance with yet another embodiment of the present invention; and

FIGS. 22 to 27 are plan views illustrating examples of a plasma source in accordance with a fifth embodiment of the present invention.

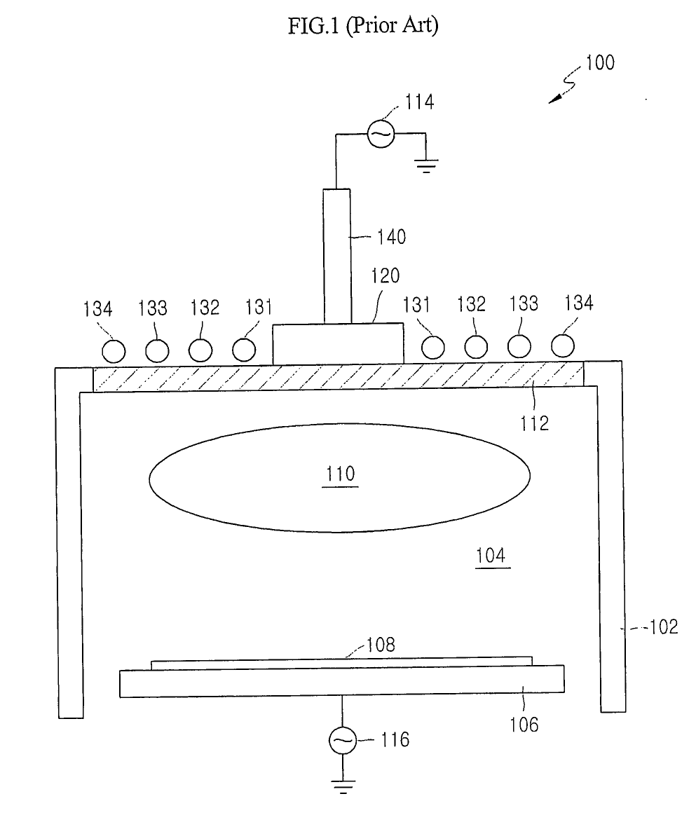

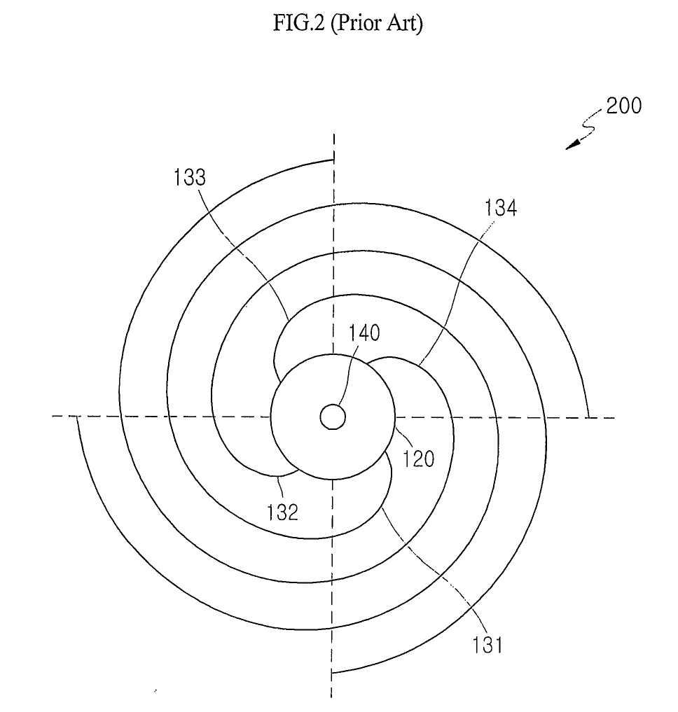

### DESCRIPTION OF THE PREFERRED EMBODIMENTS

Preferred embodiments of the present invention will be described with reference to accompanying drawings.

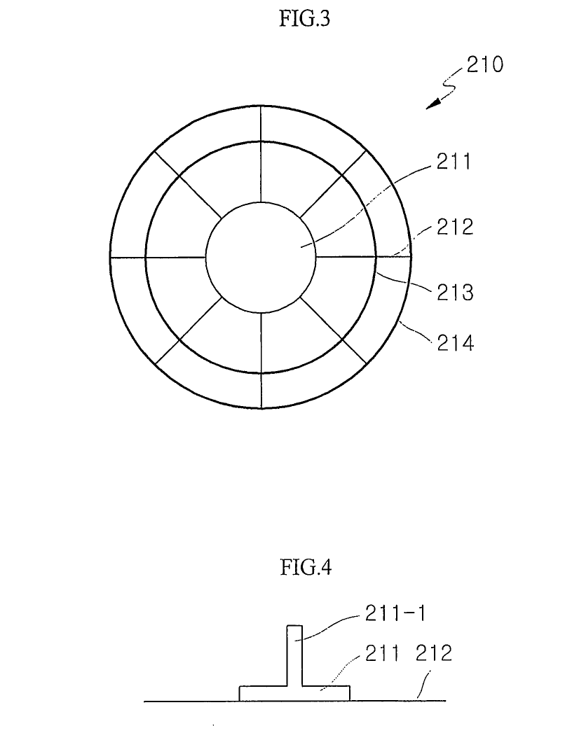

FIG. 3 is a plan view illustrating a plasma source in accordance with a first embodiment of the present invention, and FIG. 4 is a cross-sectional view illustrating the plasma source of FIG. 3.

Referring to FIGS. 3 and 4, a plasma source 210 of the first embodiment comprises a bushing 211, a middle source coil 213, a peripheral source coil 214, and a plurality of linear source coils 212. The bushing 211 is formed of an electrically conductive material, and, although not shown in the drawings, the bushing 211 is located at an upper center of a reaction chamber. The bushing 211 has a protrusion 211-1 located at the center of the bushing 211 to transmit RF power from an external RF power source (not shown) to the bushing 211. The linear source coils 212 linearly extend from a periphery of the bushing 211 to an upper periphery of the reaction chamber. Since the bushing 211 is electrically connected to the linear source coils 212, the RF power supplied through the bushing 211 is also supplied to the linear source coils 212. Although the linear source coils 212 are disposed symmetrically in this embodiment, the linear source coils 212 may be non-symmetrically disposed in order to alter the plasma distribution. The peripheral source coil 214 is located at an upper periphery of the reaction chamber to surround the bushing 211 while being separated from the bushing 211 by a predetermined distance. Generally, the peripheral source coil 214 connects all distal ends of the linear source coils 212, and thus is disposed in a circular shape. The middle source coil 213 is located between the bushing 211 and the peripheral source coil 214, and, as with the peripheral source coil 214, it is circularly disposed to surround the bushing 211 while being separated from the bushing 211 by a predetermined distance. The middle source coil 213 also connects all the distal ends of the linear source coils 212. Thus, the linear source coils 212 are connected to each other via the middle source coil 213 and the peripheral source coil 214.

The plasma source 210 of this embodiment comprises the linear source coils 212 extending from the bushing 211 to the periphery of the reaction chamber. With this structure, the plasma source 210 has a magnetic field intensity given by the following equation:

dB=(μ₀/4π)[(Idl×\check{r})/R²] (2)

where B denotes magnetic flux density, μ₀ denotes permeability, I denotes electric current, \check{r} denotes the unit vector, and R denotes distance.

When producing magnetic field with such a linear structure, it is possible to prevent deviation in magnetic field from the center to the periphery of the plasma source in the radial direction, resulting in easy control of critical dimensions and uniform etching rate both at the center and the periphery of the plasma source.

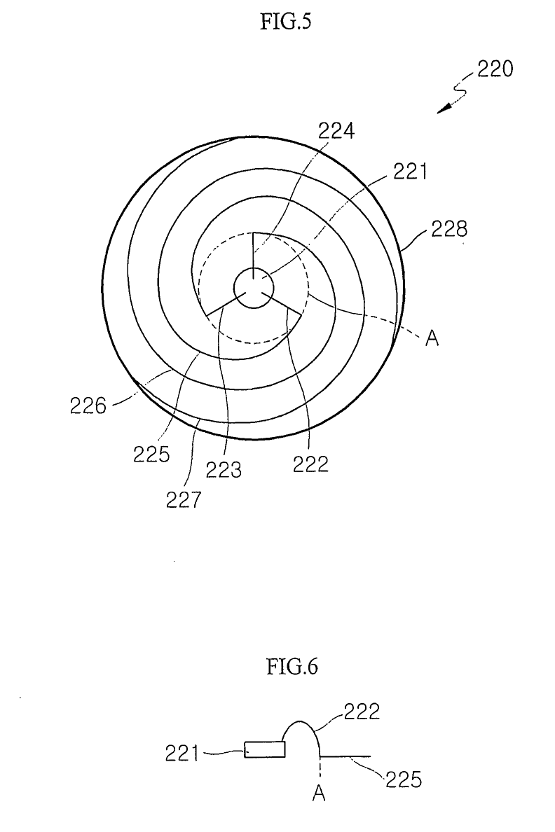

FIG. 5 is a plan view illustrating a plasma source in accordance with a second embodiment of the present invention, and FIG. 6 is a cross-sectional view illustrating the plasma source of FIG. 5.

Referring to FIGS. 5 and 6, a plasma source 220 of the second embodiment comprises a bushing 221, first source coils 222, 223 and 224, second source coils 225, 226 and 227, and a peripheral source coil 228. The bushing 221 is located at an upper center of the reaction chamber. In the plasma source 220 of this embodiment, the bushing 221 is also formed of an electrically conductive material, and this is the same as that of embodiments described below. The first source coils 222, 223 and 224 are located in a first circular region A surrounding the bushing 221, and the second source coils 225, 226 and 227 are located between the first region A and the circular peripheral source coil 228 surrounding the first region A. More specifically, the first source coils 222, 223 and 224 radially extend from the bushing 221 in the first region A to a periphery of the first region A, in which each of the first source coils 222, 223 and 224 has a shape curved towards an upper portion of the reaction chamber. The second source coils 225, 226 and 227 spirally extend from the first source coils 222, 223 and 224 to the peripheral source coil 228 between the first region A and the peripheral source coil 228. The peripheral source coil 228 connects all distal ends of the second source coils 225, 226 and 227.

The plasma source 220 of this embodiment comprises the first source coils 222, 223 and 224 having a linear structure extending from the bushing 221 to the first region A, and a magnetic field intensity as shown in Equation 2 is produced with such a linear structure. When producing the magnetic field with such a linear structure, it is possible to prevent deviation in magnetic field from the center to at least the first region A of the plasma source in the radial direction, resulting in easy control of critical dimensions and uniform etching rate both at the center and the periphery of the plasma source by controlling the size of the first region A.

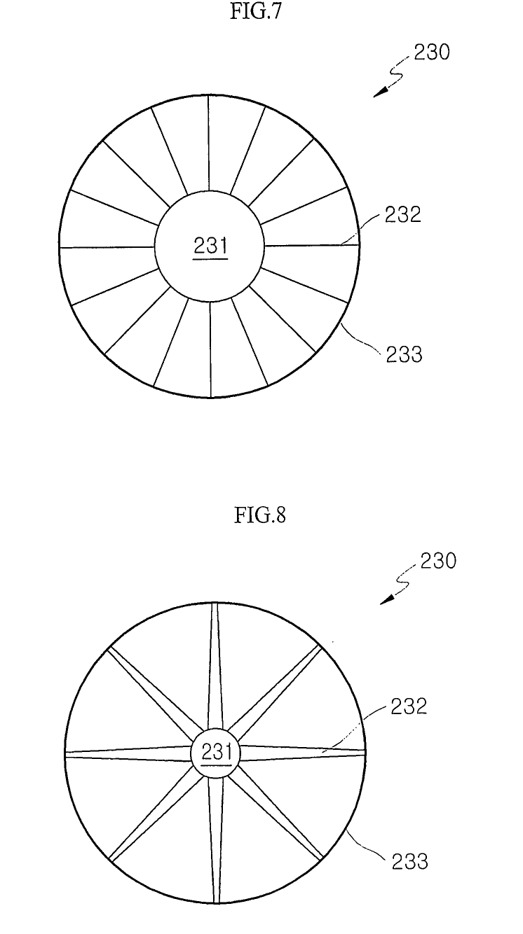

FIG. 7 is a plan view illustrating a plasma source in accordance with a third embodiment of the present invention.

Referring to FIG. 7, a plasma source 230 of the third embodiment comprises a bushing 231, and a plurality of bar-shaped source coils 232. More specifically, the bushing 231 is located at an upper center of the reaction chamber. The plasma source 230 further comprises a peripheral source coil 233 circularly provided around the bushing 231 and separated a predetermined distance from the bushing 231. Although the bushing 231 and the peripheral source coil 233 are described as having a circular shape in this embodiment, they may have different shapes, as a matter of course. The plurality of source coils 232 have bar shapes, each extending from the bushing 231 and being linearly disposed to the peripheral source coil 233.

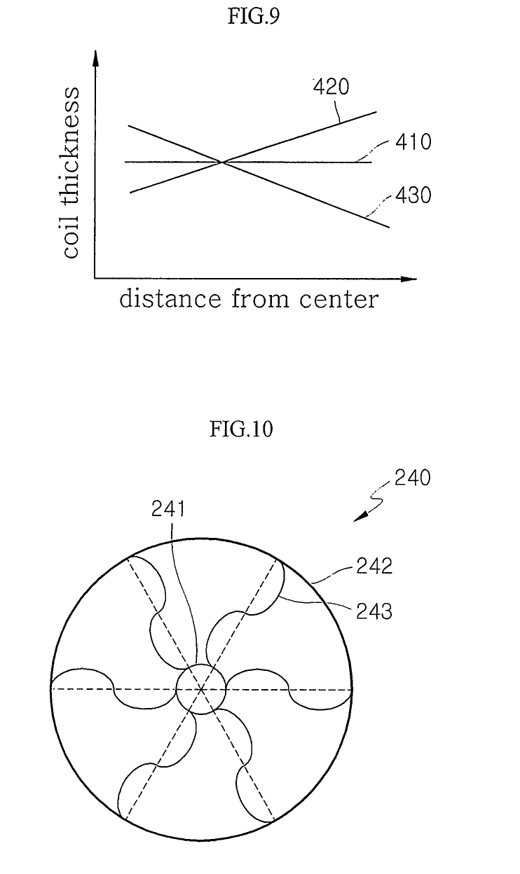

FIG. 8 is a plan view illustrating a plasma source in accordance with a fourth embodiment of the present invention, and FIG. 9 is a graph depicting the relationship between coil thickness and distance from the center of the plasma source of FIG. 8. In FIG. 8, the same reference numerals as those of FIG. 7 denote the same elements as those of FIG. 7.

Referring to FIG. 8, each of source coils 232 linearly extending from the bushing 231 to the peripheral source coil 233 has a thickness, which is not constant from a portion of the source coil connected to the bushing 231 to the peripheral source coil 233. For example, the thickness of each source coil 232 is gradually increased in the direction toward the bushing 231, whereas thickness of each the source coil 232 is gradually decreased in the direction away from the bushing 231, i.e. in the direction of the peripheral source coil 233. That is, as shown in FIG. 9, the thickness of the plurality of source coils 232 may be constant independent of a distance from the center of the plasma source (see 410), may be increased as the distance from the center of the plasma source is increased (see 420), or may be decreased as the distance from the center of the plasma source is increased (see 430). The change in thickness of the source coils 232 causes current density to be changed, resulwhich influences a plasma density. Accordingly, a desired plasma density can be obtained by changing the thicknesses of the source coils 232 to prevent non-uniformity of the plasma density.

FIG. 10 is a plan view illustrating a plasma source in accordance with a fifth embodiment of the present invention.

Referring to FIG. 10, a plasma source 240 of the fifth embodiment comprises an electrically conductive bushing 241 equipped at an upper center of the reaction chamber, and a plurality of radial source coils 243 extending in a wave shape from the bushing 241 to a periphery of the reaction chamber. At this time, distal ends of the radial source coils 243 are connected to each other via a peripheral source coil 242. Preferably, the radial source coils 243 are disposed in the wave shape having an integral wavelength from the bushing 241 to the peripheral source coil 243.

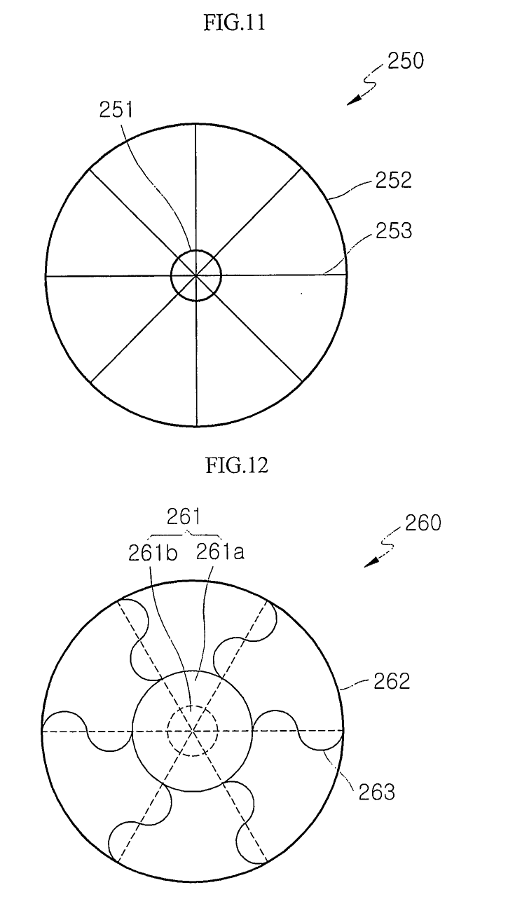

FIG. 11 is a plan view illustrating a plasma source in accordance with a sixth embodiment of the present invention.

Referring to FIG. 11, a plasma source 250 of the sixth embodiment comprises a plurality of radial source coils 253 linearly extending from an upper center of the reaction chamber to a periphery of the reaction chamber, and a circular peripheral source coil 252 connecting all distal ends of the plurality of radial source coils 253 at an upper periphery of the reaction chamber.

The plasma source 250 further comprises a circular middle source coil 251 connecting all the source coils 253 between the center of the plasma source and the peripheral source coil 253. A distance from the center of the plasma source 250 to the middle source coil 251 is shorter than a distance from the middle source coil 251 to the peripheral source coil 253.

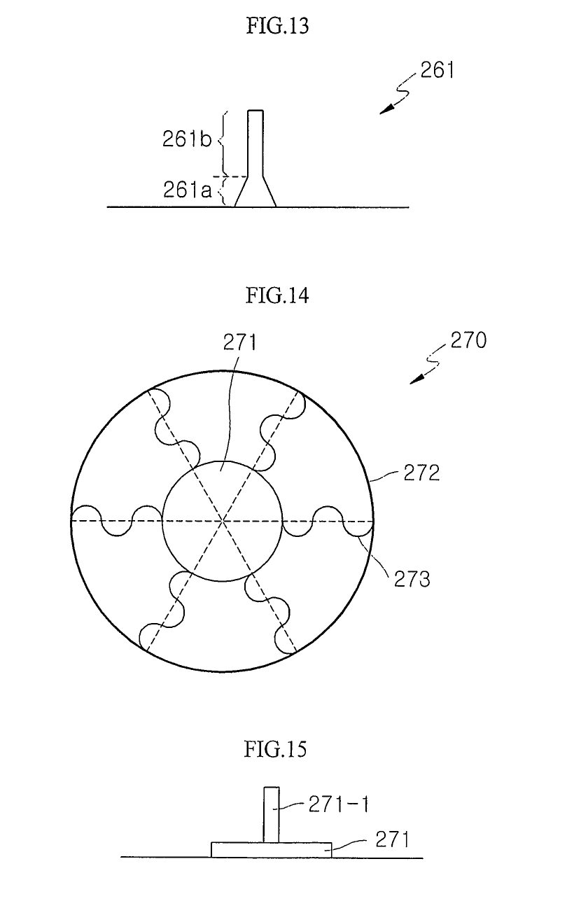

FIG. 12 is a plan view illustrating a plasma source in accordance with a seventh embodiment of the present invention, and FIG. 13 is a cross-sectional view illustrating the plasma source of FIG. 12.

Referring to FIGS. 12 and 13, a plasma source 260 of the seventh embodiment comprises a bushing 261 equipped at an upper center of the reaction chamber, a circular peripheral source coil 262 surrounding the bushing 261, and a plurality of radial source coils 263 disposed between the bushing 261 and the peripheral source coil 262. The bushing 261 comprises a first section 261a, which has a greater area and is located at a lower portion of the plasma source 260, and a second section 261b, which has a smaller area and is located on an upper surface of the first section 261a. In particular, the first section 261a located at the lower portion of the plasma source 260 has a non-constant cross-section. For example, in order to reduce the plasma density at the center of the plasma source, the first section 261a has a cross-section gradually decreasing from a lower portion to the upper portion of the plasma source. Each of the radial source coils 263 extends in a wave shape from the first section 261a of the bushing 261 to the peripheral source coil 263. In particular, the radial source coils 243 are disposed in the wave shape having a predetermined wavelength with respect to a central axis defined by a line (dotted line) from the center of the bushing 261 to the peripheral source coil 263. At this time, distal ends of the radial source coils 263 are connected to each other via the peripheral source coil 263.

FIG. 14 is a plan view illustrating a plasma source in accordance with an eighth embodiment of the present invention, and FIG. 15 is a cross-sectional view illustrating the plasma source of FIG. 14.

Referring to FIGS. 14 and 15, a plasma source 270 of the eighth embodiment has the same construction as that of the plasma source 260 of the seventh embodiment shown in FIGS. 12 and 13, including the disposition of the peripheral source coil 272 and the like, except for the shape of a bushing 271 and a waveform of a plurality of radial source coils 273. In the plasma source 270 of the eighth embodiment, a protrusion 271-1 is placed at the center of the bushing 271 to supply RF power from an external RF power source (not shown) to the bushing 271, and is not changed in cross-section in the vertical direction. Additionally, in the plasma source 270 of the eighth embodiment, each of the radial source coils 273 has a wave shape having 3/2 oscillations, which is different from the wave shape of the radial source coil 263 having one oscillation in the plasma source 260 shown in FIG. 12.

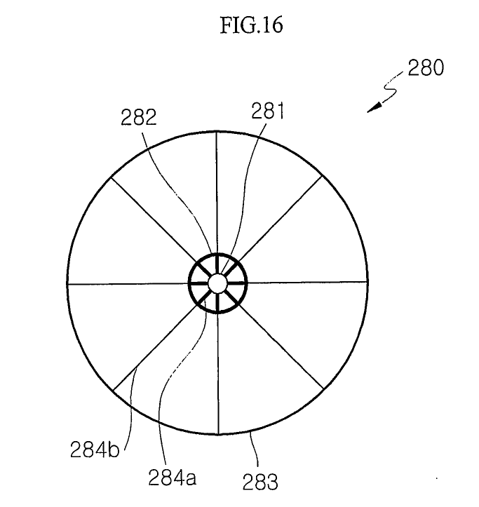

FIG. 16 is a plan view illustrating a plasma source in accordance with a ninth embodiment of the present invention.

Referring to FIG. 16, a plasma source 280 of the ninth embodiment comprises an electrically conductive bushing 281 equipped at an upper center of the reaction chamber, at least one middle source coil 282 surrounding the bushing 281, a plurality of first linear source coils 284a linearly extending from the bushing 281 to the middle source coil 283, a peripheral source coil 283 surrounding the middle source coil 282, and a plurality of second linear source coils 284b linearly extending from the first linear source coils 284a to the peripheral source coil 283.

Although the bushing 281, the middle source coil 282, the peripheral source coil 283, the first linear source coils 284a, and the second linear source coils 284b are electrically conductive, they are formed of different materials. That is, the middle source coil 282 and the first linear source coils 284a are formed of a first electrically conductive material, and the peripheral source coil 283 and the second linear source coils 284b are formed of a second electrically conductive material. As such, different conductivities between the first conductive material and the second conductive material cause the plasma density to differ at the center of the reaction chamber and at the periphery of the reaction chamber. Accordingly, it is possible to specifically determine the first conductive material and the second conductive material depending on a desired plasma distribution.

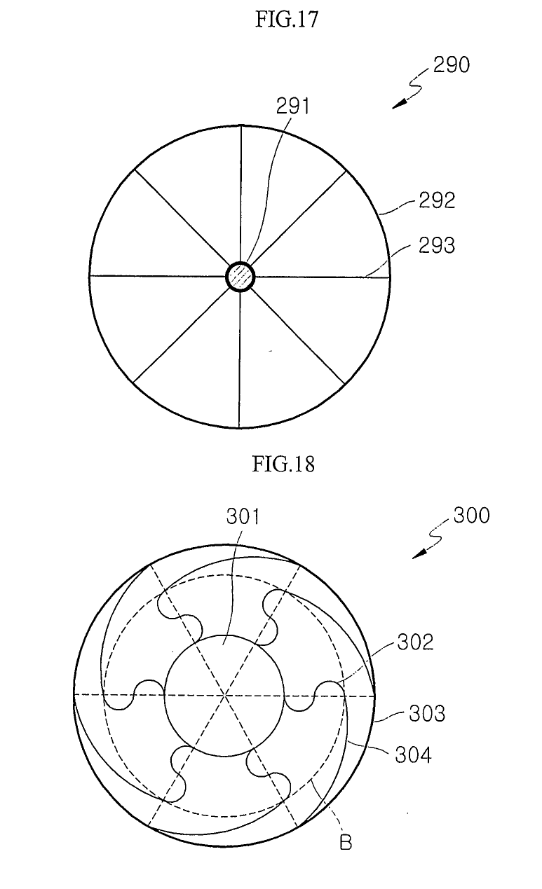

FIG. 17 is a plan view illustrating a plasma source in accordance with a tenth embodiment of the present invention.

Referring to FIG. 17, a plasma source 290 of the tenth embodiment comprises an electrically conductive bushing 291 equipped at an upper center of the reaction chamber, a peripheral source coil 292 surrounding the bushing 291, and a plurality of linear source coils 293 linearly extending from the bushing 291 to the peripheral source coil 292. The bushing 291 is formed of a first electrically conductive material, and the peripheral source coil 292 and the linear source coils 293 are formed of a second electrically conductive material. In the case of the tenth embodiment, it is also possible to specifically determine the first conductive material and the second conductive material depending on a desired distribution of plasma.

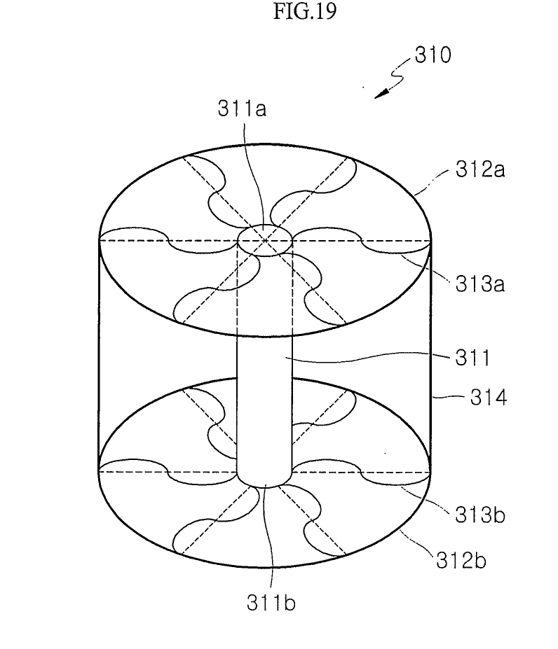

FIG. 18 is a plan view illustrating a plasma source in accordance with an eleventh embodiment of the present invention.

Referring to FIG. 18, a plasma source 300 of the eleventh embodiment comprises an electrically conductive bushing 301 equipped at an upper center of the reaction chamber, a plurality of first source coils 302 extending from the bushing 301 to a first circular region B separated by a first distance from the bushing 301 while surrounding the bushing 301, a peripheral source coil 303 surrounding the first region B, and a plurality of second source coils 304 extending from the first source coils 302 to the peripheral source coil 303. The first source coils 302 are disposed in a wave shape, and the second source coils 304 are disposed in a spiral shape.

FIG. 19 is a plan view illustrating a plasma source in accordance with a twelfth embodiment of the present invention.

Referring to FIG. 19, a plasma source 310 of the twelfth embodiment comprises an electrically conductive columnar-shaped bushing 311 vertically located at an upper center of the reaction chamber, in which the bushing 311 has an upper surface 311a positioned a substantial distance from the reaction chamber and a lower surface 311b adjacent the reaction chamber. A plurality of upper source coils 313a extend in a wave shape from the bushing 311 to a periphery of the reaction chamber, and are coplanar with the upper surface of the bushing 311. Distal ends of the plurality of upper source coils 313a are connected to each other via a peripheral upper source coil 312a. A plurality of lower source coils 313b extend in a wave shape from the bushing 311 to the periphery of the reaction chamber, and are coplanar with the lower surface of the bushing 311. Distal ends of the plurality of lower source coils 313b are connected to each other via a peripheral lower source coil 312b. The peripheral upper source coil 313a and the peripheral lower source coil 313b are connected to each other via a vertical source coil 314, which is disposed vertical to the upper surface of the reaction chamber.

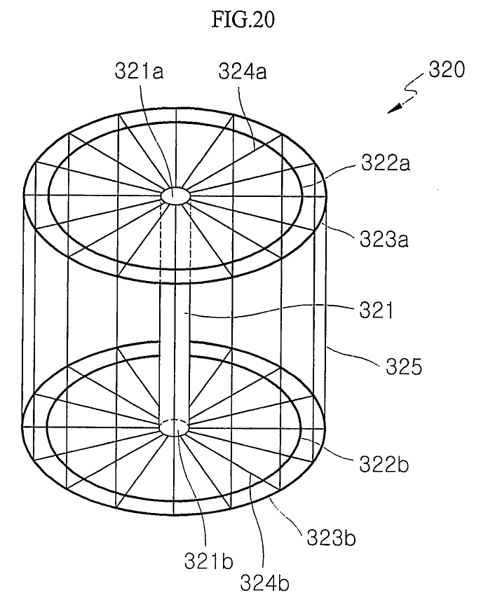

FIG. 20 is a plan view illustrating a plasma source in accordance with a thirteenth embodiment of the present invention.

Referring to FIG. 20, a plasma source 320 of the thirteenth embodiment comprises an electrically conductive columnar-shaped bustling 321 vertically located at an upper center of the reaction chamber, in which the bushing 321 has an upper surface 321a in a long distance from the reaction chamber and a lower surface 321b adjacent the reaction chamber. Plural upper linear source coils 324a linearly extend from the bushing 321 to a periphery of the reaction chamber, and are coplanar with the upper surface of the bushing 311. Distal ends of the plural upper linear source coils 324a are connected to each other via a peripheral upper source coil 323a, which has a circular shape, and is disposed around an upper periphery of the reaction chamber. Additionally, the plural upper linear source coils 324a are connected to each other via a middle upper source coil 322a which has a circular shape, and is disposed between the bushing 321 and the peripheral upper source coil 323a.

A plurality of lower linear source coils 324b linearly extend from the bushing 321 to the periphery of the reaction chamber, and are coplanar with the lower surface of the bushing 321. Distal ends of the plurality of lower linear source coils 324b are connected to each other via a peripheral lower source coil 323b, which has a circular shape, and is disposed around a lower periphery of the reaction chamber. Additionally, the plurality of lower linear source coils 324b are connected to each other via a middle lower source coil 322b which has a circular shape, and is disposed between the bushing 321 and the peripheral lower source coil 323a. The peripheral upper source coil 323a and the peripheral lower source coil 323b are connected to each other via a vertical source coil 325, which is disposed vertical to the upper surface of the reaction chamber.

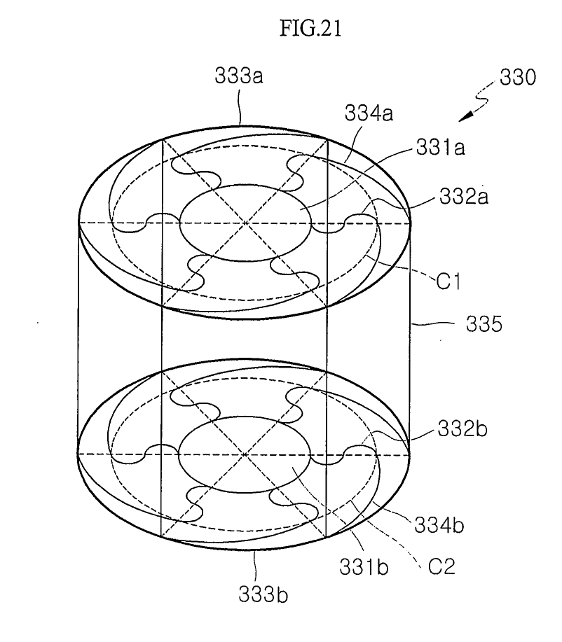

FIG. 21 is a plan view illustrating a plasma source in accordance with a fourteenth embodiment of the present invention.

Referring to FIG. 21, a plasma source 330 of the fourteenth embodiment comprises an electrically conductive upper bushing 331a located on an upper plane positioned a substantial distance from the reaction chamber, and an electrically conductive lower bushing 331b located on a lower plane adjacent the reaction chamber. That is, the upper bushing 331a vertically separated from the lower bushing 331b.

A plurality of first upper source coils 332a are located on the upper plane, where the upper bushing 331a is located. The first upper source coils 332a extend in a wave shape from the upper bushing 331a to a first region C1 separated by a first distance from the upper bushing 331a. Additionally, a plurality of second upper source coils 334a spirally extend on the upper plane from the first upper source coils 332a to a second region separated by a second distance from the first region C1 while surrounding the first region C1. A peripheral upper source coil 333a is disposed around a periphery of the reaction chamber to connect distal ends of the second upper source coils 334a to each other on the upper plane.

A plurality of first lower source coils 332b are located on the lower plane, where the lower bushing 331b is located. The first lower source coils 332b extend in a wave shape from the lower bushing 331a to a third region C2 separated by a third distance from the upper bushing 331b. Additionally, a plurality of second lower source coils 334b spirally extend on the lower plane from the first lower source coils 332b to a fourth region separated by a fourth distance from the third region C2 while surrounding the third region C2. A peripheral lower source coil 333b is disposed around the periphery of the reaction chamber to connect distal ends of the second lower source coils 334b to each other on the lower plane. The peripheral upper source coil 333a and the peripheral lower source coil 333b are connected to each other via a vertical source coil 335, which is disposed vertical to the upper surface of the reaction chamber.

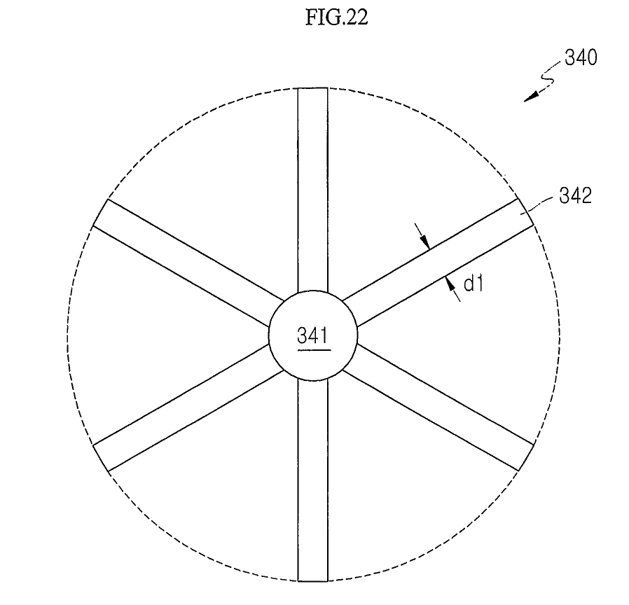

FIGS. 22 to 27 are plan views illustrating examples of a plasma source in accordance with a fifteenth embodiment of the present invention. The plasma source of this embodiment is different from the first to fourth embodiments in that it does not comprise the peripheral source coil.

Referring to FIG. 22, one example of a plasma source 340 according to the fifteenth embodiment comprises a bushing 341 located at the center of the plasma source 340, and a plurality of conductors 342 linearly extending from the bushing 341 in a radial direction of the plasma source 340. The bushing 341 is formed of an electrically conductive material, and although not shown in the drawing, it is collected to an external RF power source (not shown). Each of the conductors 342 is radially disposed in a stripe shape, and has a predetermined thickness d1. Preferably, the conductors 342 are disposed symmetrically. In this case, although the number of conductors 342 is even, the present invention is not limited to this structure. Additionally, although not shown in the drawing, each conductor 342 is not limited to a particular cross-sectional shape, and thus it may have, for example, a circular shape or other polygonal shapes.

Unlike the conventional plasma source, the plasma source 340 constructed as described above creates a magnetic field which is induced in a circular shape, so that the magnetic field is uniformly distributed in both an azimuth angle and a radial direction. With uniform distribution of the magnetic field in both azimuth angle and radial directions, enhanced selectivity and uniform CD distribution can be achieved.

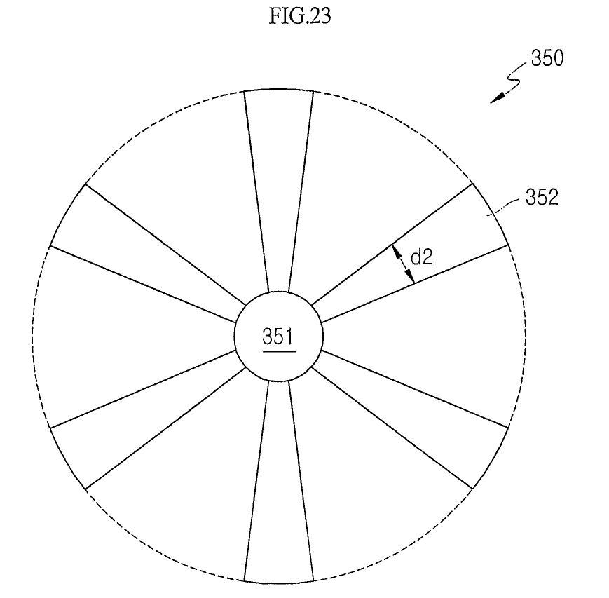

Next, referring to FIG. 23, another example of the plasma source 350 according to the fifteenth embodiment comprises a bushing 351 located at the center of the plasma source 350, and a plurality of conductors 352 linearly extending from the bushing 351 in a radial direction of the plasma source 350. Unlike the plasma source 340 shown in FIG. 22, the plasma source 350 has the conductors 352, each of which has a thickness d2 gradually increasing in the radial direction from the bushing 351. This structure serves the purpose of changing magnetic field intensity produced according to variation in the thickness d2 of the conductor 352, resulting in variation of plasma density. At this time, variation in the thickness of the conductors 352 depends on a desired process within the reaction chamber using the plasma source 350 of this example. For example, since the conductors 352 have a lower thickness d2 adjacent to the bushing 351, and a higher thickness d2 away from the bushing 351, the magnetic field intensity is decreased as a distance from the bushing 351 is increased. Thus, this example can be employed for a process requiring decrease in plasma density at an outer periphery of the reaction chamber rather than at the center of the reaction chamber.

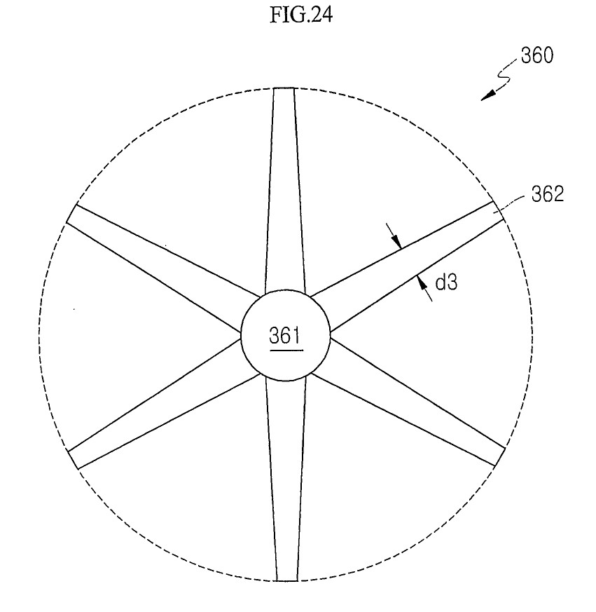

Next, referring to FIG. 24, yet another example of a plasma source 360 according to the fifteenth embodiment comprises a bushing 361 located at the center of the plasma source 360, and a plurality of conductors 362 linearly extending from the bushing 361 in a radial direction of the plasma source 360. Unlike the plasma source 340 shown in FIG. 22, the plasma source 360 has the conductors 362, each of which has a non-constant thickness d3. More specifically, the thickness d3 of the conductors 362 gradually decreases in a direction radially outward from the bushing 361, whereas the thickness d2 of the conductors 352 gradually increases in a direction radially outward from the bushing 351. This structure serves the purpose of changing magnetic field intensity produced according to variation in the thickness d3 of the conductor 362, resulting in variation of plasma density. At this time, variation in the thickness of the conductors 362 depends on a desired process within the reaction chamber using the plasma source 360 of this example. For example, since the conductors 362 have a higher thickness d3 adjacent to the bushing 361, and a lower thickness d3 away from the bushing 361, the magnetic field intensity is increased as a distance from the bushing 361 is increased. Thus, this example can be employed for a process requiring decreased plasma density at the center of the reaction chamber rather than at the periphery of the reaction chamber.

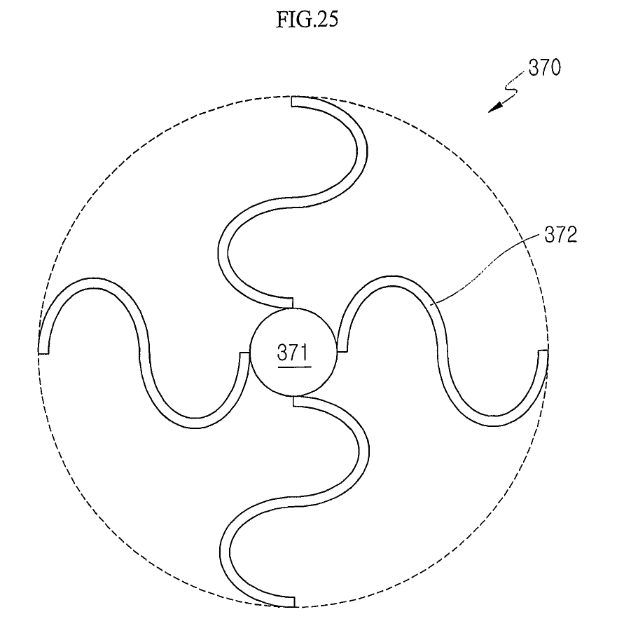

Next, referring to FIGS. 25 to 27, other examples of the plasma sources 370, 380 and 390 of the fifteenth embodiment comprise bushings 371, 381 and 391 located at the center of the plasma sources 370, 380 and 390, and a plurality of conductors 372, 382 and 392 radially extending from the bushings 371, 381 and 391, respectively. Unlike the plasma sources 340, 350 and 360 having the conductors 342, 352 and 362 disposed in the stripe shape or in the line, as shown in FIGS. 22 to 24, the plasma sources 370, 380 and 390 have conductors 372, 382, and 392, respectively, which are disposed in a curved stripe shape or in a curved line.

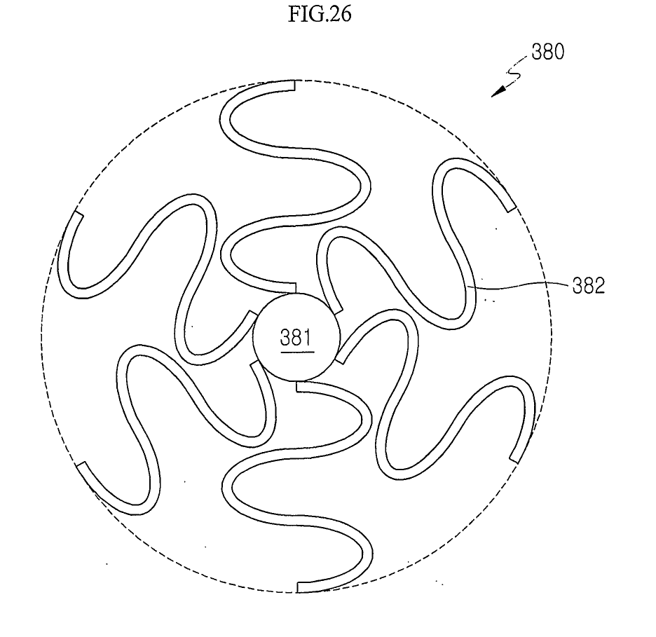

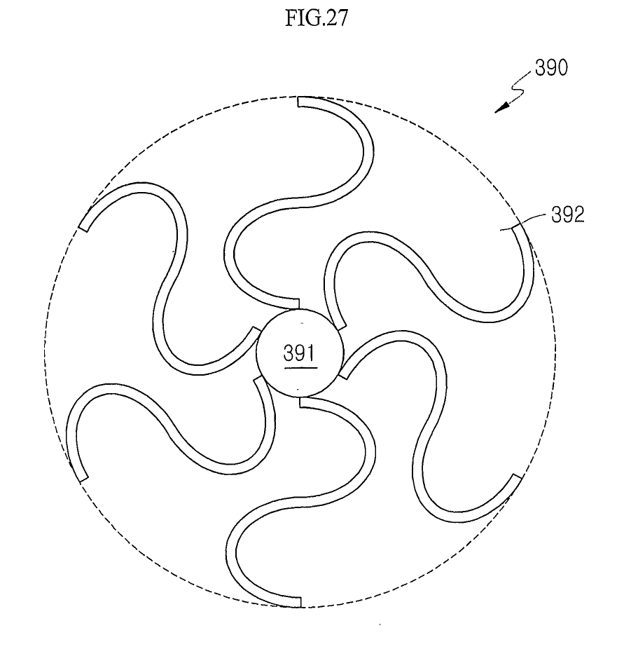

The plasma source 370 of FIG. 25 has four conductors 372, the plasma source 380 of FIG. 26 has six conductors 382, and the plasma source 390 of FIG. 27 has eight conductors 392. In addition to this, more conductors may be disposed symmetrically. Curvature of the conductors 372, 382 and 392 is not limited, and the conductors 372, 382 and 392 may have an S-shape or a W-shape as illustrated in the drawing.

In the plasma sources 370, 380 and 390, the conductors 372, 382 and 392 may have a constant thickness or a non-constant thickness. In the case where the conductors 372, 382 and 392 have the non-constant thickness, the thickness may be gradually increased or decreased as distances from the bushings 371, 381 and 291 are increased. The thickness is determined according to a process to be performed as described above.

The invention can be applied to a semiconductor manufacturing apparatus employing a plasma chamber, and a method thereof.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A plasma source for producing plasma within a reaction chamber for processing a semiconductor wafer, comprising:
an electrically conductive bushing equipped at an upper center of the reaction chamber; and
a plurality of source coils linearly extending from the bushing to a periphery of the reaction chamber.

2. The plasma source according to claim 1, wherein the plurality of source coils are disposed symmetrically.

3. The plasma source according to claim 1, wherein each of the source coils has a non-constant thickness from a portion connected to the bushing to the periphery of the reaction chamber.

4. The plasma source according to claim 1, further comprising:
a peripheral source coil separated from the bushing by a predetermined distance while surrounding the bushing around an upper periphery of the reaction chamber, and having a circular shape to connect all the plurality of source coils to each other.

5. The plasma source according to claim 4, further comprising:
at least one middle source coil separated from the bushing by a predetermined distance while surrounding the bushing between the bushing and the peripheral source coil, and having a circular shape to connect all the plurality of source coils to each other.

6. A plasma source for producing plasma within a reaction chamber for processing a semiconductor wafer, comprising:
an electrically conductive bushing equipped at an upper center of the reaction chamber;
a plurality of first source coils radially extending from the bushing in a first region surrounding the bushing to a periphery of the first region, each first source coil having a shape curved towards an upper portion of the reaction chamber; and
a plurality of second source coils spirally extending from the first source coils in a second region surrounding the first region to a periphery of the second region.

7. A plasma source for producing plasma within a reaction chamber for processing a semiconductor wafer, comprising:
an electrically conductive bushing equipped at an upper center of the reaction chamber; and
a plurality of source coils extending in a wave shape from the bushing to a periphery of the reaction chamber.

8. A plasma source for producing plasma within a reaction chamber for processing a semiconductor wafer, comprising:
a plurality of source coils linearly extending from an upper center of the reaction chamber to a periphery of the reaction chamber; and
a circular peripheral source coil connecting all distal ends of the plurality of source coils around an upper periphery of the reaction chamber.

9. The plasma source according to claim 8, further comprising:
at least one middle source coil circularly disposed within the peripheral source coil while being separated from the peripheral source coil by a predetermined distance to connect all the source coils.

10. A plasma source for producing plasma within a reaction chamber for processing a semiconductor wafer, comprising:
an electrically conductive bushing equipped at an upper center of the reaction chamber, the bushing comprising a first section having a greater area and being located at a lower portion of the reaction chamber, and a second section having a smaller area and being located on an upper surface of the first section;
a plurality of source coils extending in a wave shape from the first section of the bushing to a periphery of the reaction chamber; and
a circular peripheral source coil connecting all distal ends of the source coils at an upper periphery of the reaction chamber.

11. The plasma source according to claim 10, wherein the first section is gradually decreased from a bottom surface to a portion contacting the second section.

12. A plasma source for producing plasma within a reaction chamber for processing a semiconductor wafer, comprising:
an electrically conductive bushing equipped at an upper center of the reaction chamber;
at least one middle source coil surrounding the bushing;
a plurality of first linear source coils linearly extending from the bushing to the middle source coil;
a peripheral source coil surrounding the middle source coil; and
a plurality of second linear source coils linearly extending from the first linear source coils to the peripheral source coil, wherein the middle source coil and the first linear source coils are formed of a material different from that of the peripheral source coil and the second linear source coils.

13. A plasma source for producing plasma within a reaction chamber for processing a semiconductor wafer, comprising:
an electrically conductive bushing equipped at an upper center of the reaction chamber;
a peripheral source coil surrounding the bushing; and
a plurality of linear source coils linearly extending from the bushing to the peripheral source coil, wherein the bushing, the peripheral source coil, and the linear source coils are formed of different materials.

14. A plasma source for producing plasma within a reaction chamber for processing a semiconductor wafer, comprising:
an electrically conductive bushing equipped at an upper center of the reaction chamber;
a plurality of first source coils extending in a wave shape from the bushing to a first region separated by a first distance from the bushing while surrounding the bushing; and
a plurality of second source coils spirally extending from the first source coils to a second region separated by a second distance from the first region while surrounding the first region.

15. A plasma source for producing plasma within a reaction chamber for processing a semiconductor wafer, comprising:
an electrically conductive columnar-shaped bushing vertically located at an upper center of the reaction chamber, the bushing having an upper surface positioned a substantial distance from the reaction chamber and a lower surface adjacent the reaction chamber;
a plurality of upper source coils extending in a wave shape from the bushing to a periphery of the reaction chamber, and coplanar with the upper surface of the bushing; and
a plurality of lower source coils extending in a wave shape from the bushing to the periphery of the reaction chamber, and coplanar with the lower surface of the bushing.

16. The plasma source according to claim 15, further comprising:
an upper peripheral source coil coplanar with the upper surface of the bushing and connecting distal ends of the upper source coils;
a lower peripheral source coil coplanar with the lower surface of the bushing and connecting distal ends of the lower source coils; and
a vertical source coil vertically connecting the upper peripheral source coil and the lower peripheral source coil.

17. A plasma source for producing plasma within a reaction chamber for processing a semiconductor wafer, comprising:
an electrically conductive columnar-shaped bushing vertically located at an upper center of the reaction chamber, the bushing having an upper surface positioned a substantial distance from the reaction chamber and a lower surface adjacent the reaction chamber;
a plurality of upper source coils linearly extending from the bushing to a periphery of the reaction chamber, and coplanar with the upper surface of the bushing; and
a plurality of lower source coils linearly extending from the bushing to the periphery of the reaction chamber, and coplanar with the lower surface of the bushing.

18. The plasma source according to claim 17, further comprising:
a peripheral upper source coil coplanar with the upper surface of the bushing and connecting all distal ends of the upper source coils;
at least one middle upper source coil located coplanar with the upper surface of the bushing between the bushing and the peripheral upper source coil;
a peripheral lower source coil circularly located coplanar with the lower surface of the bushing and connecting all distal ends of the lower source coils;
at least one middle lower source coil located coplanar with the lower surface of the bushing between the bushing and the peripheral lower source coil; and
a vertical source coil vertically connecting the peripheral upper source coil and the peripheral lower source coil.

19. A plasma source for producing plasma within a reaction chamber for processing a semiconductor wafer, comprising:
an electrically conductive upper bushing located on an upper plane positioned a substantial distance from the reaction chamber;
a plurality of first upper source coils extending in a wave shape from the upper bushing to a first region separated by a first distance from the upper bushing;
a plurality of second upper source coils spirally extending from the first upper source coils on the upper plane to a second region separated by a second distance from the first region while surrounding the first region;
a peripheral upper source coil connecting distal ends of the second upper source coils on the upper plane;
an electrically conductive lower bushing located on a lower plane adjacent the reaction chamber;
a plurality of first lower source coils extending in a wave shape from the lower bushing to a third region separated by a third distance from the lower bushing;
a plurality of second lower source coils spirally extending from the first lower source coils on the lower plane to a fourth region separated by a fourth distance from the third region while surrounding the third region;
a peripheral lower source coil connecting distal ends of the second lower source coils on the lower plane; and
a vertical source coil vertically connecting the peripheral upper source coil and the peripheral lower source coil.

20. A plasma source for producing plasma within a reaction chamber for processing a semiconductor wafer, comprising:
a bushing located at a center of the reaction chamber; and
a plurality of conductors radially extending in a stripe shape from the bushing.

21. The plasma source according to claim 20, wherein the conductors are disposed symmetrically.

22. The plasma source according to claim 20, wherein the bushing comprises a conductive material.

23. The plasma source according to claim 20, wherein each of the conductors has a thickness gradually increasing from the bustling to edge of the reaction chamber.

24. The plasma source according to claim 20, wherein each of the conductors has a thickness gradually decreasing from the bushing to edge of the reaction chamber.

25. A plasma source for producing plasma within a reaction chamber for processing a semiconductor wafer, comprising:
a bushing located at a center of the reaction chamber; and
a plurality of conductors radially extending in a curved-stripe shape from the bushing.

26. The plasma source according to claim 25, wherein the conductors are disposed symmetrically.

27. The plasma source according to claim 25, wherein the bushing comprises a conductive material.

28. The plasma source according to claim 25, wherein each of the conductors has an S-shape or a W shape.

29. The plasma source according to claim 25, wherein each of the conductors has a thickness gradually increasing from the bushing to edge of the reaction chamber.

30. The plasma source according to claim 25, wherein each of the conductors has a thickness gradually decreasing from the bushing to edge of the reaction chamber.
